(19) United States
(12) Patent Application Publication
(10) Pub. No.: US 2024/0105841 A1
(43) Pub. Date: Mar. 28, 2024

(54) VERTICAL-TRANSPORT FIELD-EFFECT TRANSISTORS WITH HIGH PERFORMANCE OUTPUT

(71) Applicant: International Business Machines Corporation, Armonk, NY (US)

(72) Inventors: Brent A. Anderson, Jericho, VT (US); Albert M. Chu, Nashua, NH (US); Lawrence A. Clevenger, Saratoga Springs, NY (US); Ruilong Xie, Niskayuna, NY (US); Nicholas Anthony Lanzillo, Wynantskill, NY (US); REINALDO VEGA, Mahopac, NY (US)

(21) Appl. No.: 17/936,164

(22) Filed: Sep. 28, 2022

(51) Int. Cl. H01L 29/78; H01L 27/02; H01L 29/417

(52) U.S. Cl. CPC H01L 29/7827; H01L 27/0207; H01L 29/41741

(57) ABSTRACT

A vertical-transport field-effect transistor (VTFET) is on a wafer. The VTFET has a first width. The first width is a contacted poly pitch (CPP). A bottom source/drain region of the VTFET extends at least the first width from the VTFET. A contact from a frontside of the VTFET is connected to the bottom source/drain region.

### BACKGROUND OF THE INVENTION

The present invention relates generally to the field of semiconductor device manufacture and more particularly to vertical-transport field-effect transistors (VTFET) with a high-performance output.

Semiconductor devices are fabricated by sequentially depositing insulating (dielectric) layers, conductive layers, and semiconductor layers of material over a semiconductor substrate, and patterning the various layers using lithography to form circuit components and elements thereon. Generally, these semiconductor devices include a plurality of circuits which form an integrated circuit (IC) fabricated on a semiconductor substrate.

VTFET devices allow for the flow of current vertically, from a bottom source/drain region to a top source/drain region. In a VTFET device, a bottom source/drain region is located closest to the wafer, a gate region is on top of the bottom source/drain region and a top source/drain region is on top of the gate region. The bottom source/drain region is located closest to the wafer the circuit is formed upon and the top source/drain region is located farthest from the wafer the circuit is formed upon. When an even number of VTFET are placed in series, in other words a source/drain region of a first VTFET is directly connected to a source/drain region of a second VTFET, the bottom source/drain region of the last VTFET in the series has an output on the bottom of the circuitry, in other words closest to the wafer. Here, the challenge is the output must be directed to the frontside of the circuitry in order for the output to be routed to other circuitry via traditional interconnect wiring in the metal layers above the device layer the VTFET in series are located.

### SUMMARY

In a first embodiment, a vertical-transport field-effect transistor (VTFET) is on a wafer. In the first embodiment, the VTFET has a first width, and wherein the first width is a contacted poly pitch (CPP). In the first embodiment, a bottom source/drain region of the VTFET extends at least the first width from the VTFET. In the first embodiment, a contact from a frontside of the VTFET is connected to the bottom source/drain region.

In the first embodiment, the contact is connected to the bottom source/drain region on a frontside of the bottom source/drain region. In the first embodiment, the contact is connected to the bottom source/drain region on a backside of the bottom source/drain region. In the first embodiment, the contact is greater than the first width wide. In the first embodiment, the contact from the frontside of the VTFET connected to the bottom source/drain region is an output connection.

Embodiments of the present invention provide for increased contact are to the backside of bottom source/drain regions of VTFET devices. Embodiments of the present invention provide for lower resistance for high performance device using backside power. Embodiments of the present invention provide for any number of signals (e.g., clock, buss, I/O, power, ground, etc.) to be distributed or delivered to source/drain/gate regions of VTFET through a backside power delivery network.

In a second embodiment, a first plurality of vertical-transport field-effect transistor (VTFET) on a wafer. In the second embodiment, a portion of the first plurality of VTFET has a first width. In the second embodiment, the first width is a contacted poly pitch (CPP). In the second embodiment, a second plurality of VTFET are adjacent to the first plurality of VTFET on the wafer. In the second embodiment, a portion of the second plurality of VTFET has the first width. In the second embodiment, a shared top contact is connected to each top source/drain region of the first plurality of VTFET and second plurality of VTFET. In the second embodiment, a bottom source/drain region of the first plurality of VTFET extending at least the first width from a first VTFET of the first plurality of VTFET and the bottom source/drain region of first plurality of VTFET is connected to each VTFET of the first plurality of VTFET. In the second embodiment, a contact from a frontside of the wafer connected to the bottom source/drain region of the first plurality of VTFET.

In the second embodiment, the contact may be connected to the bottom source/drain region of the first plurality of VTFET on a frontside of the bottom source/drain region. In the second embodiment, the contact may be connected to the bottom source/drain region of the first plurality of VTFET on a backside of the bottom source/drain region. In the second embodiment, the contact is greater than the first width wide. In the second embodiment, the contact from the frontside of the VTFET connected to the bottom source/drain region is an output connection.

Embodiments of the present invention provide for increased contact are to the backside of bottom source/drain regions of VTFET devices. Embodiments of the present invention provide for a shared output within a single CPP with adjacent circuits in both the lateral and vertical direction. Embodiments of the present invention avoid higher resistance paths of supply power through RX, or active area, regions to contact regions.

In a third embodiment, a first plurality of vertical-transport field-effect transistor (VTFET) on a wafer. In the third embodiment, each VTFET of the first plurality of VTFET has a first width and the first width is a contacted poly pitch (CPP). In the third embodiment, a second plurality of VTFET are on the wafer and the second plurality of VTFET are adjacent to the first plurality of VTFET. In the third embodiment, a bottom source/drain region of the first plurality of VTFET extends at least the first width from a first VTFET of the first plurality of VTFET. In the third embodiment, a top contact connected to a top source/drain region of the second plurality of VTFET, wherein the top contact extending at least the first width from a second VTFET of the second plurality of VTFET.

In the third embodiment, a bottom contact is connected to the bottom source/drain region and a metal line in a first metal layer and the first metal layer is above the first plurality of VTFET and second plurality of VTFET. In the third embodiment, the top contact is connected to the metal line. In the third embodiment, an active region within the first width adjacent to the first plurality of VTFET and the second plurality of VTFET and the active region connects to a metal line in a first metal layer. In the third embodiment, the bottom source/drain region is connected to the active region. In the third embodiment, the top contact is connected to the active region. In the third embodiment, the contact from the frontside of the VTFET connected to the bottom source/drain region is an output connection. In the third embodiment, e contact is greater than the first width wide.

Embodiments of the present invention provide for increased contact are to the backside of bottom source/drain regions of VTFET devices. Embodiments of the present invention provide for lower resistance for high performance device using backside power supply. Embodiments of the present invention provide for a larger contact are to the RX, or active area, region which provides lower resistance. Embodiments of the present invention provide for a shared output within a single CPP with adjacent circuits in both the lateral and vertical direction. Embodiments of the present invention avoid higher resistance paths of supply power through RX, or active area, regions to contact regions. Embodiments of the present invention provide for any number of signals (e.g., clock, buss, I/O, power, ground, etc.) to be distributed or delivered to source/drain/gate regions of VTFET through a backside power delivery network.

### BRIEF DESCRIPTION OF THE DRAWINGS

The above and other aspects, features, and advantages of various embodiments of the present invention will be more apparent from the following description taken in conjunction with the accompanying drawings.

FIG. 1 depicts a cross-section view of a VTFET semiconductor structure with a frontside contact for the top source/drain region, bottom source/drain region, and gate region, in accordance with a first embodiment of the present invention.

FIG. 2 depicts a cross-section view of a VTFET semiconductor structure with a frontside contact for the top source/drain region and gate region and a backside contact for the bottom source/drain region, in accordance with a first embodiment of the present invention.

FIG. 3 depicts a cross-section view of a VTFET semiconductor structure with a frontside contact for the top source/drain and a backside contact for the bottom source/drain region and gate region, in accordance with a first embodiment of the present invention.

FIG. 4A depicts a top view of the semiconductor structure including two sets in series of two VTFET in parallel in accordance with an embodiment of the present invention.

FIG. 4B depicts a cross-sectional view of section A of the semiconductor structure including two sets in series of two VTFET in parallel in accordance with a first embodiment of the present invention.

FIG. 4C depicts a cross-sectional view of section A of the semiconductor structure including two sets in series of two VTFET in parallel in accordance with a second embodiment of the present invention.

FIG. 4D depicts a cross-sectional view of section A of the semiconductor structure including two sets in series of two VTFET in parallel in accordance with a third embodiment of the present invention.

FIG. 5A depicts a top view of the semiconductor structure including two sets in series of two VTFET in parallel in a first row and four VTFET in parallel in a second row with connected outputs, in accordance with a first embodiment of the present invention.

FIG. 5B depicts a cross-sectional view of section X1 of the semiconductor structure including two sets in series of two VTFET in parallel in a first row and four VTFET in parallel in a second row with connected outputs, in accordance with a first embodiment of the present invention.

FIG. 6A depicts a top view of the semiconductor structure including two sets in series of two VTFET in parallel in a first row and four VTFET in parallel in a second row with connected outputs, in accordance with a second embodiment of the present invention.

FIG. 6B depicts a cross-sectional view of section X2 of the semiconductor structure including two sets in series of two VTFET in parallel in a first row and four VTFET in parallel in a second row with connected outputs, in accordance with a second embodiment of the present invention.

FIG. 7 depicts a top view of the semiconductor structure with a shared output region for multiple rows of semiconductor structures in accordance with an embodiment of the present invention.

### DETAILED DESCRIPTION

Embodiments of the present invention recognize that vertical-transport field-effect transistors (VTFET) have vertical current flow. Embodiments of the present invention recognize that VTFET include a bottom source/drain region and a top source/drain region. Embodiments of the present invention recognize that the bottom source/drain region is closer to the backside of the VTFET (closer to the wafer) and that the top source/drain region is closer to the frontside of the VTFET (closer to the traditional interconnect wiring). Embodiments of the present invention recognize that an input will be to one source/drain region and the output will be to one source/drain region and therefore one of either the input or the output will be on the backside of the device and one of either the input or the output will be on the frontside of the device. Therefore, embodiments of the present invention recognize there is a need for a bottom source/drain on the backside of the VTFET to reach the frontside of the semiconductor device. Embodiments of the present invention recognize that in conventional VTFETs, the pitch (or width) between gates in adjacent devices in the same semiconductor layer is commonly known as a contacted gate pitch (CGP) or a contact poly pitch (CPP).

Embodiments of the present invention provide for increased contact are to the backside of bottom source/drain regions of VTFET devices. Embodiments of the present invention provide for lower resistance for high performance device using backside power supply. Embodiments of the present invention provide for a larger contact are to the RX, or active area, region which provides lower resistance. Embodiments of the present invention provide for a shared output within a single CPP with adjacent circuits in both the lateral and vertical direction. Embodiments of the present invention avoid higher resistance paths of supply power through RX, or active area, regions to contact regions. Embodiments of the present invention provide for any number of signals (e.g., clock, buss, I/O, power, ground, etc.) to be distributed or delivered to source/drain/gate regions of VTFET through a backside power delivery network.

Some embodiments will be described in more detail with reference to the accompanying drawings, in which the embodiments of the present disclosure have been illustrated. However, the present disclosure can be implemented in various manners, and thus should not be construed to be limited to the embodiments disclosed herein. Reference will now be made in detail to the embodiments of the present invention, examples of which are illustrated in the accompanying drawings, wherein like reference numerals refer to like elements throughout.

The following presents a summary to provide a basic understanding of one or more embodiments of the disclosure. This summary is not intended to identify key or critical elements or delineate any scope of the particular embodiments or any scope of the claims. Its sole purpose is to present concepts in a simplified form as a prelude to the more detailed description that is presented later. It is to be understood that aspects of the present invention will be described in terms of a given illustrative architecture; however, other architectures, structures, substrate materials, process features and steps can be varied within the scope of aspects of the present invention.

Detailed embodiments of the claimed structures and methods are disclosed herein. The method steps described below do not form a complete process flow for manufacturing integrated circuits, such as semiconductor devices. The present embodiments can be practiced in conjunction with the integrated circuit fabrication techniques currently used in the art, for advanced semiconductor devices, and only so much of the commonly practiced process steps are included as are necessary for an understanding of the described embodiments. The figures represent cross-section portions of a portion of an advanced semiconductor device after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

For purposes of the description hereinafter, the terms “upper,” “lower,” “right,” “left,” “vertical,” “horizontal,” “top”, “bottom,” and derivatives thereof shall relate to the disclosed structures and methods, as oriented in the drawing figures. The terms “overlying,” “atop,” “over,” “on “positioned on,” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

In the interest of not obscuring the presentation of the embodiments of the present invention, in the following detailed description, some of the processing steps, materials, or operations that are known in the art may have been combined for presentation and illustration purposes and in some instances may not have been described in detail. Additionally, for brevity and maintaining a focus on distinctive features of elements of the present invention, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

The present embodiments can include a design for an integrated circuit chip, which can be created in a graphical computer programming language and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SixGe1-x where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

References in the specification to “one embodiment”, “other embodiment”, “another embodiment,” “an embodiment,” etc., indicate that the embodiment described may include a particular feature, structure, or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure or characteristic in connection with other embodiments whether or not explicitly described.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not tended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations and the spatially relative descriptors used herein can be interpreted accordingly. In addition, be understood that when a layer is referred to as being “between” two layers, it can be the only layer between the two layers, or one or more intervening layers cat also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The pattern created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“ME”). In general, ME uses chemically reactive plasma to remove material deposited on wafers. High-energy ions from the ME plasma attack the wafer surface and react with the surface material(s) to remove the surface material(s).

Deposition processes for the metal liners and sacrificial materials include, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Vertical transport field-effect transistors (VTFETs) have become viable device options for scaling semiconductor devices (e.g., complementary metal oxide semiconductor (CMOS) devices) to 5 nanometer (nm) node and beyond. VTFET devices include one or more fin channels with source/drain regions at ends of the fin channels on the top and bottom sides of the fins. Current flows through the fin channels in a vertical direction (e.g., perpendicular to a substrate), for example, from a bottom source/drain region to a top source/drain region. Vertical transport architecture devices are designed to address the limitations of horizontal device architectures in terms of, for example, density, performance, power consumption, and integration by, for example, decoupling gate length from the contact gate pitch, providing a FiN-FET-equivalent density at a larger contacted poly pitch (CPP), and providing lower middle-of-line (MOL) resistance.

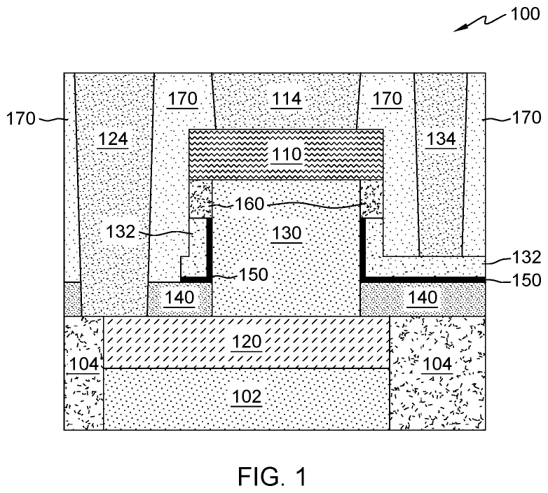

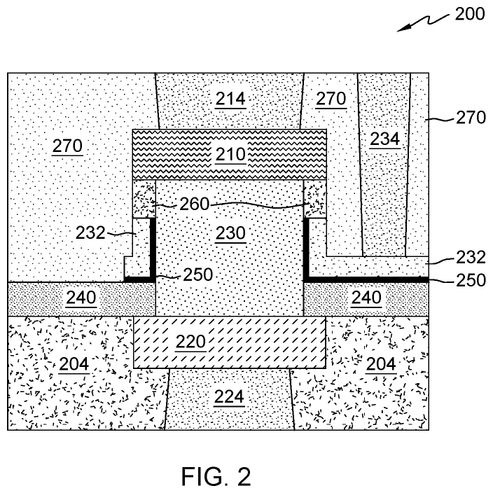

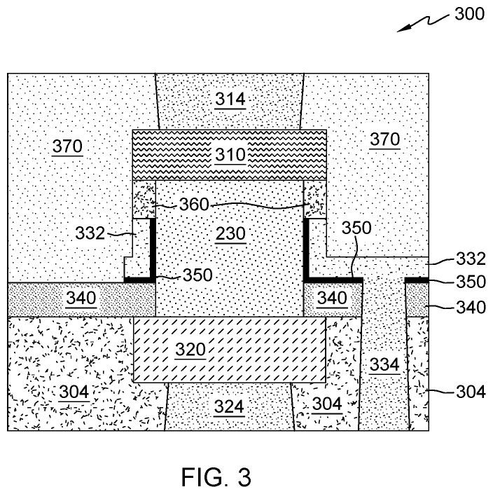

In a first embodiment, FIG. 1 shows a VTFET 100 with contact 114, contact 124, and contact 134 connected directly to interconnect wiring and/or a power delivery network (not shown) on the frontside of VTFET 100. In a second embodiment, FIG. 2 shows a VTFET 200 with contact 214 and contact 234 connected directly to interconnect wiring and/or a power delivery network (not shown) on the frontside of VTFET 200 and a contact 224 connected directly to interconnect wiring and/or a power delivery network (not shown) on the backside of VTFET 200. In a third embodiment, FIG. 3 shows a VTFET 300 with contact 314 connected directly to interconnect wiring and/or a power delivery network (not shown) on the frontside of VTFET 300 and contact 324 and contact 334 connected directly to interconnect wiring and/or a power delivery network (not shown) on the backside of VTFET 300.

FIG. 1 is a cross-sectional view of a VTFET 100 formed on a bulk substrate 102. The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

VTFET 100 includes STI region 104 comprised of a dielectric material such as silicon oxide or silicon oxynitride, and is formed by methods known in the art. For example, in one illustrative embodiment, STI region 104 is a shallow trench isolation oxide layer.

VTFET 100 includes top source/drain region 110 and bottom source/drain region 120 on either end of fin 130. In an embodiment, top source/drain region 110 is formed between dielectric layer 170. In an embodiment, bottom source/drain region 120 is formed in substrate 102 between shallow trench isolation region 104. Top source/drain region 110 and bottom source/drain region 120 are formed by, for example, epitaxial growth processes. The epitaxially grown top source/drain region 110 and bottom source/drain region 120 can be in-situ doped, meaning dopants are incorporated into the epitaxy film during the epitaxy process. Other alternative doping techniques can be used, including but not limited to, for example, ion implantation, gas phase doping, plasma doping, plasma immersion ion implantation, cluster doping, infusion doping, liquid phase doping, solid phase doping, etc., and dopants may include, for example, an n-type dopant selected from a group of phosphorus (P), arsenic (As) and antimony (Sb), and a p-type dopant selected from a group of boron (B), gallium (Ga), indium (In), and thallium (Tl) at various concentrations. For example, in a non-limiting example, a dopant concentration range may be 1×10¹⁸/cm³ to 1×10²¹/cm³. According to an embodiment, the bottom source/drain region 120 can be boron doped SiGe for a p-type field-effect transistor (P-FET) or phosphorous doped silicon for an n-type field-effect transistor (N-FET). It is to be understood that the term “source/drain region” as used herein means that a given source/drain region can be either a source region or a drain region, depending on the application.

Terms such as “epitaxial growth and/or deposition” and “epitaxially formed and/or grown” refer to the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Examples of various epitaxial growth processes include, for example, rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for an epitaxial deposition process can range from 500° C. to 900° C. Although higher temperature typically results in faster deposition, the faster deposition may result in crystal defects and film cracking.

A number of different sources may be used for the epitaxial growth of the compressively strained layer. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used. After epi formation, drive-in anneals can be applied to move the dopants closer to the bottom of the fin channels.

In an embodiment, as used herein, a “semiconductor fin” or fin 130 refers to a semiconductor material that includes a pair of vertical sidewalls that are parallel to each other. As used herein, a surface is “vertical” if there exists a vertical plane from which the surface does not deviate by more than three times the root mean square roughness of the surface. In an embodiment, each fin 130 has a height ranging from approximately 20 nm to approximately 200 nm, and a width ranging from approximately 5 nm to approximately 30 nm. Other heights and/or widths that are lesser than, or greater than, the ranges mentioned herein can also be used in the present application. Each fin 130 is spaced apart from its nearest neighboring fin 130 by a pitch ranging from approximately 20 nm to approximately 100 nm; the pitch is measured from one point, or reference surface, of one semiconductor fin to the exact same point, or reference surface, on a neighboring semiconductor fin. Also, the fins 130 are generally oriented parallel to each other. Although the present application describes and illustrates a single fin 108, any number of fins with gate region surrounding them may be used and the fins may be any shape.

The fin 130 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, fin 130 is silicon.

In an embodiment, bottom spacer layer 140 is formed on the STI region 104 and bottom source/drain region 120. In an embodiment, bottom spacer layer 140 is formed around fin 130. Suitable material for bottom spacer layer 140 includes, for example, silicon boron nitride (SiBN), siliconborocarbonitride (SiBCN), silicon oxycarbonitride (SiOCN), SiN and SiOₓ. Bottom spacer layer 140 can be deposited using, for example, directional deposition techniques, such as a high-density plasma (HDP) deposition and gas cluster ion beam (GCIB) deposition. The directional deposition deposits the spacer material preferably on the exposed horizontal surfaces, but not on the lateral sidewalls. Alternatively, the bottom spacer layer 140 can be formed by overfilling the space with dielectric materials, followed by chemical mechanical planarization (CMP) and dielectric recess.

In an embodiment, top spacer layer 160 is formed on the gate region between fin 130 and dielectric layer 170. In an embodiment, top spacer layer 160 is formed around fin 130. Suitable material for top spacer layer 160 includes, for example, silicon boron nitride (SiBN), siliconborocarbonitride (SiBCN), silicon oxycarbonitride (SiOCN), SiN and SiOₓ. Bottom spacer layer 140 can be deposited using, for example, directional deposition techniques, such as a high-density plasma (HDP) deposition and gas cluster ion beam (GCIB) deposition. The directional deposition deposits the spacer material preferably on the exposed horizontal surfaces, but not on the lateral sidewalls. Alternatively, the top spacer layer 160 can be formed by overfilling the space with dielectric materials, followed by chemical mechanical planarization (CMP) and dielectric recess.

A gate region is formed on bottom spacer layer 140 and around fin 130. In illustrative embodiments, gate region is deposited on bottom spacer layer 140 and around fin 130 employing, for example, ALD, CVD, RFCVD, plasma enhanced CVD (PECVD), physical vapor deposition (PVD), or molecular layer deposition (MLD). The gate region may include a gate dielectric layer 150 and a gate conductor layer 132. The gate dielectric layer 150 may be formed of a high-k dielectric material. Examples of high-k materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate conductor layer 132 may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer 132 as desired.

In an embodiment, dielectric layer 170 may be composed of, for example, silicon oxide (SiOₓ), undoped silicate glass (USG), fluorosilicate glass (FSG), borophosphosilicate glass (BPSG), a spin-on low-κ dielectric layer, a chemical vapor deposition (CVD) low-κ dielectric layer or any combination thereof. As indicated above, the term “low-κ” as used herein refers to a material having a relative dielectric constant κ which is lower than that of silicon dioxide. In an embodiment, the dielectric layer 170 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

In an embodiment, top source/drain region 110, bottom source drain region 120 and gate region are connected to interconnect wiring and/or a power delivery network (not shown) through contact 114, contact 124, and contact 134, respectively. In an embodiment, as shown in FIG. 1, contact 114, contact 124, and contact 134 to are formed to directly connect to interconnect wiring and/or a power delivery network (not shown) on the frontside of the VTFET 100. In an embodiment, contact 114, contact 124, and contact 134 may include any suitable conductive material, such as, for example, copper, aluminum, tungsten, cobalt, or alloys thereof. Examples of deposition techniques that can be used include, for example, chemical vapor deposition (CVD), plasma enhanced chemical vapor deposition (PECVD), or atomic layer deposition (ALD). In some cases, an electroplating technique can be used to form contact 114, contact 124, and contact 134.

In a second embodiment, FIG. 2 shows a VTFET 200 with contact 214 and contact 234 connected directly to interconnect wiring and/or a power delivery network (not shown) on the frontside of VTFET 200 and a contact 224 connected directly to interconnect wiring and/or a power delivery network (not shown) on the backside of VTFET 200. In the second embodiment, VTFET 200 shares substantially similar features to the features described above in reference to VTFET 100. For example, top source/drain region 210 is substantially similar to top source/drain region 110. It should be noted, while a substrate, similar to substrate 102 shown in FIG. 1, is not shown in FIG. 2, it would be known to one skilled in the art that VTFET 200 would be formed on a substrate similar to substrate 102 shown in FIG. 1.

In the second embodiment, the orientation of contacts in VTFET 200 are the primary differences as compared to VTFET 100. In the second embodiment, contact 214 and contact 234 are connected directly to interconnect wiring and/or a power delivery network (not shown) on the frontside of VTFET 200 and a contact 224 connected directly to interconnect wiring and/or a power delivery network (not shown) on the backside of VTFET 200.

In a third embodiment, FIG. 3 shows a VTFET 300 with contact 314 connected directly to interconnect wiring and/or a power delivery network (not shown) on the frontside of VTFET 300 and contact 324 and contact 334 connected directly to interconnect wiring and/or a power delivery network (not shown) on the backside of VTFET 300. In the third embodiment, VTFET 300 shares substantially similar features to the features described above in reference to VTFET 100 and VTFET 200. For example, top source/drain region 310 is substantially similar to top source/drain region 110 and top source/drain region 210. It should be noted, while a substrate, similar to substrate 102 shown in FIG. 1, is not shown in FIG. 3, it would be known to one skilled in the art that VTFET 300 would be formed on a substrate similar to substrate 102 shown in FIG. 1.

In the third embodiment, the orientation of contacts in VTFET 300 are the are the primary differences as compared to VTFET 100 and VTFET 200. In the third embodiment, contact 314 is connected directly to interconnect wiring and/or a power delivery network (not shown) on the frontside of VTFET 300 and contact 324 and contact 334 are connected directly to interconnect wiring and/or a power delivery network (not shown) on the backside of VTFET 300.

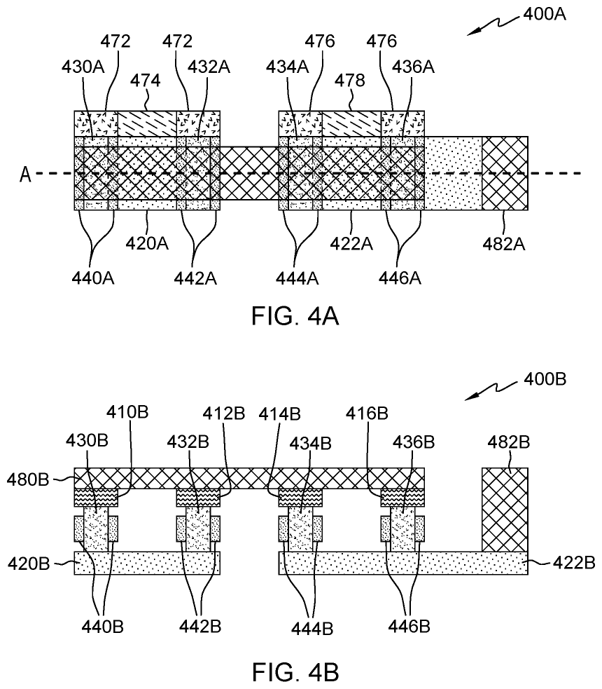

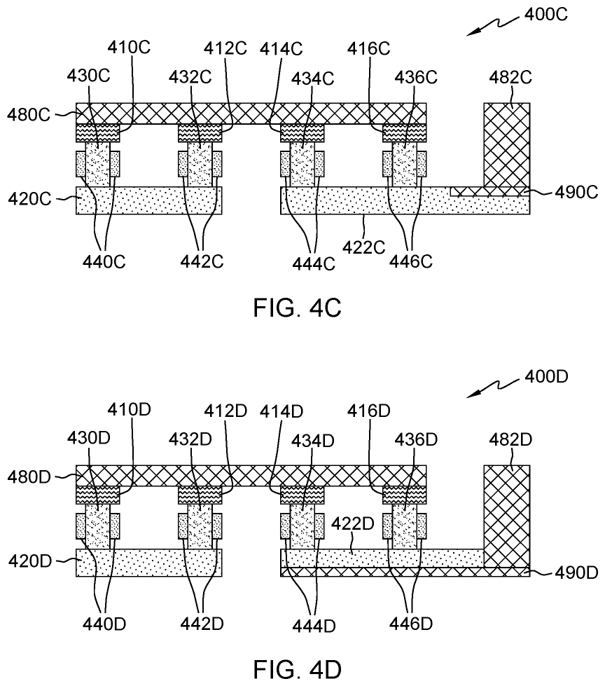

FIG. 4A depicts a top view of the semiconductor structure 400A including two sets in series of two VTFET in parallel in accordance with an embodiment of the present invention. In an embodiment, the first two VTFET in FIG. 4A are shown in parallel. In other words, a shared input is provided to the first VTFET and the second VTFET and a shared output extends from both the first VTFET and second VTFET. As shown in FIG. 4A, the first VTFET includes a shared bottom source/drain region 420A, a fin 430A, and a top source/drain region (not shown). As shown in FIG. 4A, the second VTFET includes a shared bottom source/drain region 420A, a fin 432A, and a top source/drain region (not shown). As described, the top source/drain region for each VTFET is not shown for simplicity of the drawings. It should be noted, in a preferred embodiment, the shared bottom source/drain region 420A may be connected to a backside power delivery network (not shown). In an alternative embodiment, the shared bottom source/drain region 420A may be connected to a frontside power delivery network (not shown). In an embodiment, shared bottom source/drain region 420A may be two separate bottom source/drain regions connected by a shared bottom contact which connects to a frontside or backside power delivery network (not shown).

As shown in FIG. 4A, in an embodiment, the first VTFET includes a gate region 440A surrounding at least a portion of the fin 430A and the second VTFET includes a gate region 442A surrounding at least a portion of the fin 432A. In an embodiment, semiconductor structure 400A includes a shared gate region 472 connected to both the gate region 440A and gate region 442A. In an embodiment, shared gate region 472 is connected to gate contact 474 and gate contact 474 extends towards the frontside of the semiconductor structure 400A. In an embodiment, gate contact 474 may extend towards the backside of the semiconductor structure 400A. In an alternative embodiment, shared gate region 472 may not exist, and both gate region 440A and gate region 442A may have their own gate contact (not shown) that extends towards the frontside or backside of the semiconductor structure 400A.

In an embodiment, the second two VTFET in FIG. 4A are shown in parallel. In other words, a shared input is provided to the third VTFET and the fourth VTFET and a shared output extends from both the third VTFET and fourth VTFET. As shown in FIG. 4A, the third VTFET includes a shared bottom source/drain region 422A, a fin 434A, and a top source/drain region (not shown). As shown in FIG. 4A, the fourth VTFET includes a shared bottom source/drain region 422A, a fin 436A, and a top source/drain region (not shown). As described, the top source/drain region for each VTFET is not shown for simplicity of the drawings. I

As shown in FIG. 4A, in an embodiment, the third VTFET includes a gate region 444A surrounding at least a portion of the fin 434A and the fourth VTFET includes a gate region 446A surrounding at least a portion of the fin 436A. In an embodiment, semiconductor structure 400A includes a shared gate region 476 connected to both the gate region 444A and gate region 446A. In an embodiment, shared gate region 476 is connected to gate contact 478 and gate contact 478 extends towards the frontside of the semiconductor structure 400A. In an embodiment, gate contact 478 may extend towards the backside of the semiconductor structure 400A. In an alternative embodiment, shared gate region 476 may not exist, and both gate region 444A and gate region 446A may have their own gate contact (not shown) that extends towards the frontside or backside of the semiconductor structure 400A.

As shown in FIG. 4A, in an embodiment, the semiconductor structure 400A includes a shared bottom source/drain region 422A, describe above, connected to the third VTFET and fourth VTFET. The shared bottom source/drain region 422A extends 1 CPP from the fourth VTFET before connecting to the shared frontside contact 482A. In an embodiment, the shared backside contact 482A is centered approximately 1 CPP from the center of the adjacent fourth VTFET. In an embodiment, the shared frontside contact 482A extends to connect to a frontside power delivery network (not shown).

FIG. 4B depicts a cross-sectional view of section A of the semiconductor structure 400B including two sets in series of two VTFET in parallel in accordance with a first embodiment of the present invention. As shown in FIG. 4B, the first VTFET includes a shared bottom source/drain region 420B, a fin 430B, a top source/drain region 410B, and a gate region 440B surrounding a portion of fin 430B. As shown in FIG. 4B, the second VTFET includes a shared bottom source/drain region 420B, a fin 432B, a top source/drain region 412B, and a gate region 442B surrounding a portion of fin 432B. It should be noted, in alternative embodiments, the first VTFET and second VTFET may have individual/separate bottom source/drain regions connected with a shared bottom contact (not shown). As noted above, in a preferred embodiment, the shared bottom source/drain region 420B may be connected to a backside power delivery network (not shown).

In an embodiment, as shown here, a frontside contact extends to a left edge of gate region 440A and a right edge of gate region 446A. In alternative embodiments, as known in the art, the frontside contact may extend any horizontal distance as long as frontside contact is at least electrically connected to the top source/drain region(s), described below.

As shown in FIG. 4B, the third VTFET includes a shared bottom source/drain region 422B, a fin 434B, a top source/drain region 414B, and a gate region 444B surrounding a portion of fin 434B. As shown in FIG. 4B, the fourth VTFET includes a shared bottom source/drain region 422B, a fin 436B, a top source/drain region 416B, and a gate region 446B surrounding a portion of fin 436B.

As shown in FIG. 4B, in a first embodiment, the semiconductor structure 400B includes a shared bottom source/drain region 422B, describe above, connected to the third VTFET and fourth VTFET. The shared bottom source/drain region 422B extends 1 CPP from the fourth VTFET before connecting to the shared frontside contact 482B. In an embodiment, the shared frontside contact 482B is centered approximately 1 CPP from the center of the adjacent VTFET. In an embodiment, the shared frontside contact 482B extends to connect to a frontside power delivery network (not shown). In an embodiment, the shared frontside contact 482B is substantially similar to the cell height of any of the VTFET in semiconductor structure 400B. In a first embodiment, the shared frontside contact 482B is connected directly to the shared bottom source/drain region 422B.

FIG. 4C depicts a cross-sectional view of section A of the semiconductor structure 400C including two sets in series of two VTFET in parallel in accordance with a second embodiment of the present invention. As shown in FIG. 4C, the first VTFET includes a shared bottom source/drain region 420C, a fin 430C, a top source/drain region 410C, and a gate region 440C surrounding a portion of fin 430C. As shown in FIG. 4C, the second VTFET includes a shared bottom source/drain region 420C, a fin 432C, a top source/drain region 412C, and a gate region 442C surrounding a portion of fin 432C. It should be noted, in alternative embodiments, the first VTFET and second VTFET may have individual/separate bottom source/drain regions connected with a shared bottom contact (not shown). As noted above, in a preferred embodiment, the shared bottom source/drain region 420C may be connected to a backside power delivery network (not shown).

As shown in FIG. 4C, the third VTFET includes a shared bottom source/drain region 422C, a fin 434C, a top source/drain region 414C, and a gate region 444C surrounding a portion of fin 434C. As shown in FIG. 4C, the fourth VTFET includes a shared bottom source/drain region 422C, a fin 436C, a top source/drain region 416C, and a gate region 446C surrounding a portion of fin 436C.

As shown in FIG. 4C, in a second embodiment, the semiconductor structure 400C includes a shared bottom source/drain region 422C, describe above, connected to the third VTFET and fourth VTFET. The shared bottom source/drain region 422C extends 1 CPP from the fourth VTFET before connecting to the shared frontside contact 482C. In an embodiment, the shared frontside contact 482C is centered approximately 1 CPP from the center of the adjacent VTFET. In an embodiment, the shared frontside contact 482C extends to connect to a frontside power delivery network (not shown). In an embodiment, the shared frontside contact 482C is substantially similar to the cell height of any of the VTFET in semiconductor structure 400C. In a second embodiment, the shared frontside contact 482C is connected to a metallization layer 490C on a top region of the bottom source/drain region 422C. In the second embodiment, the metallization layer 490C is within, and directly connected to, the shared bottom source/drain region 422C.

FIG. 4D depicts a cross-sectional view of section A of the semiconductor structure 400D including two sets in series of two VTFET in parallel in accordance with a third embodiment of the present invention. As shown in FIG. 4D, the first VTFET includes a shared bottom source/drain region 420D, a fin 430D, a top source/drain region 410D, and a gate region 440D surrounding a portion of fin 430D. As shown in FIG. 4D, the second VTFET includes a shared bottom source/drain region 420D, a fin 432D, a top source/drain region 412D, and a gate region 442D surrounding a portion of fin 432D. It should be noted, in alternative embodiments, the first VTFET and second VTFET may have individual/separate bottom source/drain regions connected with a shared bottom contact (not shown). As noted above, in a preferred embodiment, the shared bottom source/drain region 420D may be connected to a backside power delivery network (not shown).

As shown in FIG. 4D, the third VTFET includes a shared bottom source/drain region 422D, a fin 434D, a top source/drain region 414D, and a gate region 444D surrounding a portion of fin 434D. As shown in FIG. 4D, the fourth VTFET includes a shared bottom source/drain region 422D, a fin 436D, a top source/drain region 416D, and a gate region 446D surrounding a portion of fin 436D.

As shown in FIG. 4D, in a third embodiment, the semiconductor structure 400D includes a shared bottom source/drain region 422D, describe above, connected to the third VTFET and fourth VTFET. The shared bottom source/drain region 422D extends 1 CPP from the fourth VTFET before connecting to the shared frontside contact 482D. In an embodiment, the shared frontside contact 482D is centered approximately 1 CPP from the center of the adjacent VTFET. In an embodiment, the shared frontside contact 482D extends to connect to a frontside power delivery network (not shown). In an embodiment, the shared frontside contact 482D is substantially similar to the height of any of the VTFET in semiconductor structure 400D. In a third embodiment, the shared frontside contact 482D is connected to a metallization layer 490D on a bottom region of the bottom source/drain region 422D. In the third embodiment, the metallization layer 490D is within, and directly connected to, the shared bottom source/drain region 422D. In the third embodiment, the metallization layer 490D may extend some or all of the length of the shared bottom source/drain region 422D. In the third embodiment, the metallization layer 490D may extend some or all of the length of the shared bottom source/drain region 420D (not shown).

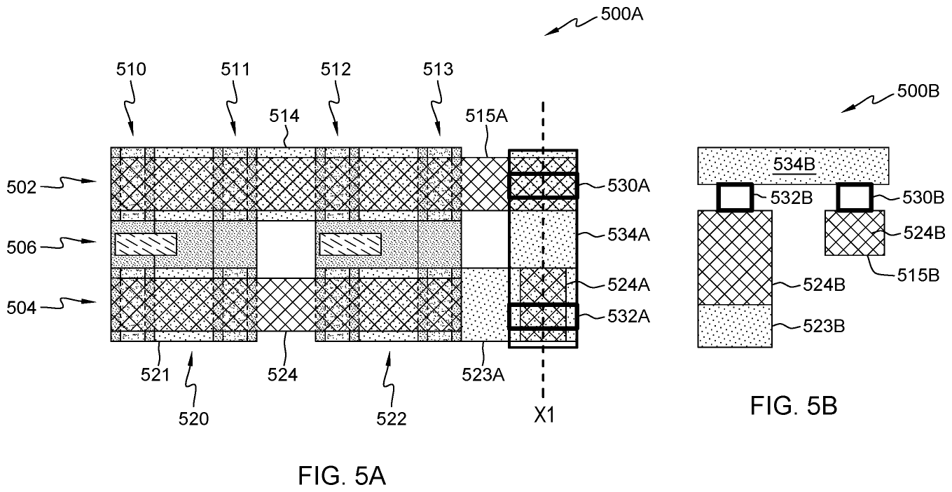

FIG. 5A depicts a top view of the semiconductor structure 500A including two sets in series of two VTFET in parallel in a first row and four VTFET in parallel in a second row with connected outputs, in accordance with a first embodiment of the present invention. As shown in FIG. 5A, in an embodiment a first row 502 of VTFET includes a first VTFET 510, second VTFET 511, third VTFET 512, and fourth VTFET 513 in parallel. VTFET 510, 511, 512, and 513 have a shared bottom source/drain region 514. As noted above, VTFET 510, 511, 512, and 513 each have a top source/drain region (not shown) connected to a shared top contact 515A. In an embodiment, shared top contact 515A extends horizontally from first row 502 one CPP from the fourth VTFET 513.

As shown in FIG. 5A, in an embodiment a second row 504 of VTFET includes a first set of VTFET 520 in parallel and a second set of VTFET 522 in parallel. In an embodiment, the first set of VTFET 520 have a shared bottom source/drain region 521. In an embodiment, the second set of VTFET 522 have a shared bottom source/drain region 523A. As noted above, the first set of VTFET 520 and second set of VTFET 522 each have a top source/drain region (not shown) connected to a shared top contact 524 making the first set of VTFET 520 and second set of VTFET 522 in series. In an embodiment, the shared bottom source/drain region 523A extends horizontally from second row 504 one CPP from the VTFET in the second set of VTFET 522 to bottom contact 524A.

In an embodiment, semiconductor structure 500A includes a shared gate region 506. In the shared gate region 506, two contacts are located that connect to frontside or backside power delivery networks (not shown). The shared gate region 506 connects to each gate region of each VTFET in the first row 502 of VTFET and second row 504 of VTFET.

In an embodiment, semiconductor structure 500A includes a frontside metal layer contact 530A in the first row 502. As shown in FIG. 5A, in an embodiment frontside metal layer contact 530A is square in shape. In alternative embodiment, frontside metal layer contact 530 may be circular, for example a via, or any other shape. In yet another alternative embodiment, frontside metal layer contact 530A may be any number of frontside metal layer contact 530A (i.e., more than one). In an embodiment, frontside metal layer contact 530A connects shared top contact 515A to a metal layer 534A. In an embodiment, semiconductor structure 500A includes a frontside metal layer contact 532A in the second row 504. As shown in FIG. 5A, in an embodiment frontside metal layer contact 532A is square in shape. In alternative embodiment, frontside metal layer contact 532A may be circular, for example a via, or any other shape. In yet another alternative embodiment, frontside metal layer contact 532A may be any number of frontside metal layer contact 532A (i.e., more than one). In an embodiment, frontside metal layer contact 532A connects bottom contact 524A to a metal layer 534A. In an embodiment, metal layer 534A may be any metal layer above the top of semiconductor structure 500A. In other words, metal layer 534A may be a metal layer above the top of any of the VTFET in semiconductor structure 500A.

In an embodiment, as shown here, a frontside contact extends to a left edge of gate region of the first row 502. In alternative embodiments, as known in the art, the frontside contact may extend any horizontal distance as long as frontside contact is at least electrically connected to the top source/drain region(s), described below. In an embodiment, as shown here, a frontside contact extends to a left edge of gate region of the second row 504 and a right edge of a gate region of the second row 504. In alternative embodiments, as known in the art, the frontside contact may extend any horizontal distance as long as frontside contact is at least electrically connected to the top source/drain region(s), described below.

FIG. 5B depicts a cross-sectional view of section X1 of the semiconductor structure 500B including two sets in series of two VTFET in parallel in a first row and four VTFET in parallel in a second row with connected outputs, in accordance with a first embodiment of the present invention. In an embodiment, semiconductor structure 500B includes a frontside metal layer contact 530B. In an embodiment, frontside metal layer contact 530B connects shared top contact 515B to a metal layer 534B. In an embodiment, semiconductor structure 500B includes a frontside metal layer contact 532B. In an embodiment, frontside metal layer contact 532B connects bottom contact 524B to a metal layer 534B. In an embodiment, bottom contact 524B is connected to shared bottom source/drain region 523B. In an embodiment, metal layer 534B may be any metal layer above the top of semiconductor structure 500B. In other words, metal layer 534B may be a metal layer above the top of any of the VTFET in semiconductor structure 500B.

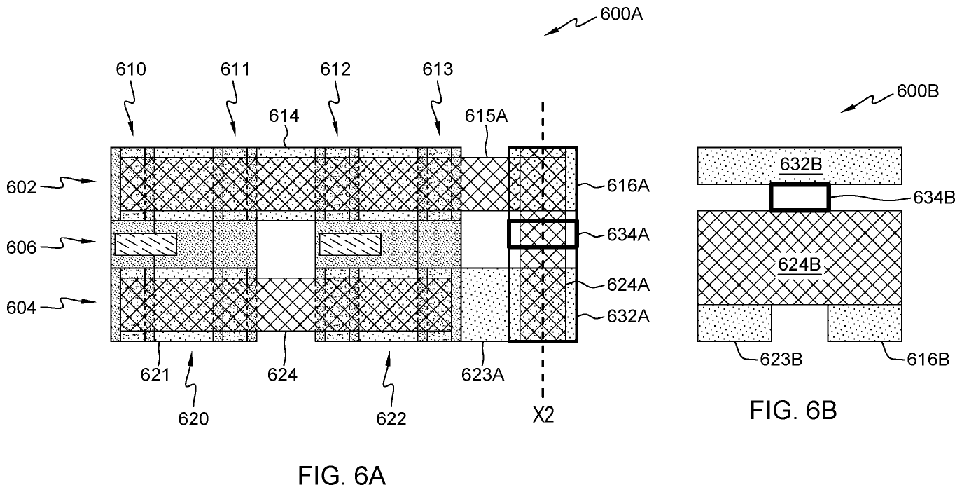

FIG. 6A depicts a top view of the semiconductor structure 600A including two sets in series of two VTFET in parallel in a first row and four VTFET in parallel in a second row with connected outputs, in accordance with a second embodiment of the present invention. As shown in FIG. 6A, in an embodiment a first row 602 of VTFET includes a first VTFET 610, second VTFET 611, third VTFET 612, and fourth VTFET 613 in parallel. VTFET 610, 611, 612, and 613 have a shared bottom source/drain region 614. As noted above, VTFET 610, 611, 612, and 613 each have a top source/drain region (not shown) connected to a shared top contact 615A. In an embodiment, shared top contact 615A extends horizontally from first row 602 one CPP from the fourth VTFET 613 to connect to an RX region 616A. In an embodiment, shared top contact 615A extends to connect with bottom contact 624A.

As shown in FIG. 6A, in an embodiment a second row 604 of VTFET includes a first set of VTFET 620 in parallel and a second set of VTFET 622 in parallel. In an embodiment, the first set of VTFET 620 have a shared bottom source/drain region 621. In an embodiment, the second set of VTFET 622 have a shared bottom source/drain region 623A. As noted above, the first set of VTFET 620 and second set of VTFET 622 each have a top source/drain region (not shown) connected to a shared top contact 624 making the first set of VTFET 620 and second set of VTFET 622 in series. In an embodiment, the shared bottom source/drain region 623A extends horizontally from second row 604 one CPP from the VTFET in the second set of VTFET 622 to bottom contact 624A. In an embodiment, the shared bottom source/drain region 623A connects to the bottom contact 624A.

In an embodiment, semiconductor structure 600A includes a shared gate region 506. In the shared gate region 606, two contacts are located that connect to frontside or backside power delivery networks (not shown). The shared gate region 606 connects to each gate region of each VTFET in the first row 602 of VTFET and second row 604 of VTFET.

In an embodiment, semiconductor structure 600A includes a frontside metal layer contact 634A. In an embodiment, the frontside metal layer contact 630A connects the bottom contact 624A to the first metal layer 632A. In an embodiment, first metal layer 632A is any metal layer above the VTFET. As shown in FIG. 6A, in an embodiment, frontside metal layer contact 634A is square in shape. In alternative embodiment, frontside metal layer contact 634A may be circular, for example a via, or any other shape.

In an embodiment, as shown here, a frontside contact extends to a left edge of gate region of the first row 602. In alternative embodiments, as known in the art, the frontside contact may extend any horizontal distance as long as frontside contact is at least electrically connected to the top source/drain region(s), described below. In an embodiment, as shown here, a frontside contact extends to a left edge of gate region of the second row 604 and a right edge of a gate region of the second row 604. In alternative embodiments, as known in the art, the frontside contact may extend any horizontal distance as long as frontside contact is at least electrically connected to the top source/drain region(s), described below.

FIG. 6B depicts a cross-sectional view of section X2 of the semiconductor structure 600B including two sets in series of two VTFET in parallel in a first row and four VTFET in parallel in a second row with connected outputs, in accordance with a second embodiment of the present invention. In an embodiment, the shared bottom source/drain region 623B is connected to bottom contact 624B. In an embodiment, RX region 616A is connected to bottom contact 624B. In an embodiment, bottom contact 624B is connected to first metal layer 632B by frontside metal layer contact 634B.

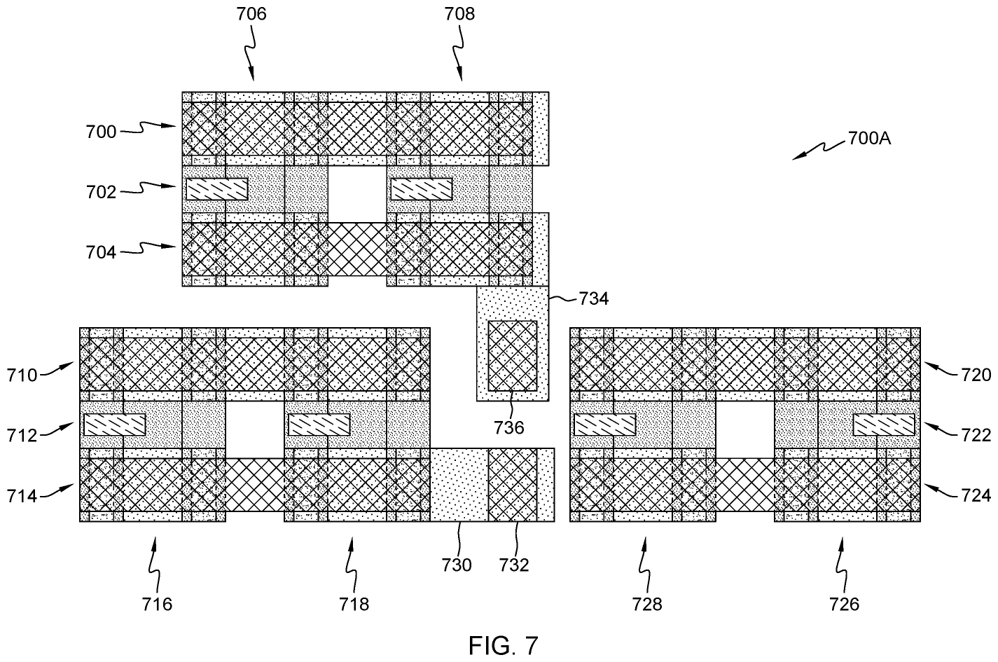

FIG. 7 depicts a top view of the semiconductor structure 700A with a shared output region for multiple rows of semiconductor structures in accordance with an embodiment of the present invention. It should be noted, semiconductor structure 700A may include any layout of VTFET devices, including non VTFET transistor devices or other circuitry (not shown). For example. Semiconductor structure 700A may include any number of VTFET in series, parallel, or any combination thereof.

As shown in FIG. 7, semiconductor structure 700A includes a first row 700 of VTFET. In the first row 700 of VTFET devices, there are four VTFET in parallel with a shared top contact connected to the top source/drain region of each VTFET of the four VTFET and a shared bottom source/drain region. In an embodiment, semiconductor structure 700A includes a second row 704 of VTFET as a first pair 706 of VTFET and second pair 708 of VTFET. In an embodiment, the first pair 706 of VTFET are in parallel with a shared bottom source/drain region and the second pair 7008 of VTFET are in parallel with a shared bottom source/drain region 734. The first pair 706 of VTFET and second pair 708 of VTFET are in series and are connected by a shared top contact that is connected to the top source/drain regions of each VTFET of the pairs of VTFET. In an embodiment, the shared bottom source/drain region 734 extends down from second pair 708 of VTFET one CPP from the VTFET in the second pair 718 of VTFET to at least bottom contact 732, discussed below, and connects to bottom contact 736. In other words, the center of bottom contact 736 is at least 1 CPP from the center of the fin of the VTFET closest to the bottom contact 732 that is in the second pair 718 of VTFET. In an embodiment, a shared gate region 702 is connected to the gate regions of each VTFET of the first row 700 of VTFET and second row 704 of VTFET, similar to discussed in embodiments above.

As shown in FIG. 7, semiconductor structure 700A includes a third row 710 of VTFET. In the third row 710 of VTFET devices, there are four VTFET in parallel with a shared top contact connected to the top source/drain region of each VTFET of the four VTFET and a shared bottom source/drain region. In an embodiment, semiconductor structure 700A includes a fourth row 714 of VTFET as a first pair 716 of VTFET and second pair 718 of VTFET. In an embodiment, the first pair 716 of VTFET are in parallel with a shared bottom source/drain region and the second pair 718 of VTFET are in parallel with a shared bottom source/drain region 730. The first pair 716 of VTFET and second pair 718 of VTFET are in series and are connected by a shared top contact that is connected to the top source/drain regions of each VTFET of the pairs of VTFET. In an embodiment, the shared bottom source/drain region 730 extends horizontally from second pair 718 of VTFET one CPP from the VTFET in the second pair 718 of VTFET to at least bottom contact 732 and connects to bottom contact 732. In other words, the center of bottom contact 732 is at least 1 CPP from the center of the fin of the VTFET closest to the bottom contact 732 that is in the second pair 718 of VTFET. In an embodiment, a shared gate region 712 is connected to the gate regions of each VTFET of the third row 710 of VTFET and fourth row 714 of VTFET, similar to discussed in embodiments above.

As shown in FIG. 7, semiconductor structure 700A includes a fifth row 720 of VTFET and sixth row 724 of VTFET. In an embodiment, in the fifth row 720 of VTFET devices, there are four VTFET in parallel with a shared top contact connected to the top source/drain region of each VTFET of the four VTFET and a shared bottom source/drain region. In an embodiment, in the sixth row 724 of VTFET devices, there are four VTFET in parallel with a shared top contact connected to the top source/drain region of each VTFET of the four VTFET and a shared bottom source/drain region. In an embodiment, a shared gate region 722 is connected to the gate regions of each VTFET of the fifth row 720 of VTFET and sixth row 724 of VTFET, similar to discussed in embodiments above. It should be noted, FIG. 7 does not show a connection from the any VTFET in the fifth row 720 or sixth row 724 to bottom contact 732 or bottom contact 736, however, connections from either the top source/drain region, bottom source/drain region, or gate region of VTFET in the fifth row 720 or sixth row 724 may connect to bottom contact 732, bottom contact 736, shared bottom source/drain region 730, and shared bottom source/drain region 734.

In an embodiment, as shown in FIG. 7, frontside contacts extend to a left edge of gate region and/or right edge of a gate region. In alternative embodiments, as known in the art, the frontside contact may extend any horizontal distance as long as frontside contact is at least electrically connected to the top source/drain region(s), described below.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a vertical-transport field-effect transistor (VTFET) on a wafer, wherein the VTFET has a first width, and wherein the first width is a contacted poly pitch (CPP);
a bottom source/drain region of the VTFET extending at least the first width from the VTFET; and
a contact from a frontside of the VTFET connected to the bottom source/drain region.

2. The semiconductor device of claim 1, wherein the contact is connected to the bottom source/drain region on a frontside of the bottom source/drain region.

3. The semiconductor device of claim 1, wherein the contact is connected to the bottom source/drain region on a backside of the bottom source/drain region.

4. The semiconductor device of claim 1, wherein the contact is greater than the first width wide.

5. The semiconductor device of claim 1, wherein the contact from the frontside of the VTFET connected to the bottom source/drain region is an output connection.

6. A semiconductor device comprising:
a first plurality of vertical-transport field-effect transistor (VTFET) on a wafer, wherein a portion of the first plurality of VTFET has a first width, and wherein the first width is a contacted poly pitch (CPP);
a second plurality of VTFET adjacent to the first plurality of VTFET on the wafer, wherein a portion of the second plurality of VTFET has the first width;
a shared top contact, wherein the shared top contact is connected to each top source/drain region of the first plurality of VTFET and second plurality of VTFET;
a bottom source/drain region of the first plurality of VTFET extending at least the first width from a first VTFET of the first plurality of VTFET, wherein the bottom source/drain region of first plurality of VTFET is connected to each VTFET of the first plurality of VTFET; and
a contact from a frontside of the wafer connected to the bottom source/drain region of the first plurality of VTFET.

7. The semiconductor device of claim 6, wherein the contact is connected to the bottom source/drain region of the first plurality of VTFET on a frontside of the bottom source/drain region.

8. The semiconductor device of claim 6, wherein the contact is connected to the bottom source/drain region of the first plurality of VTFET on a backside of the bottom source/drain region.

9. The semiconductor device of claim 6, wherein the first plurality of VTFET are in parallel.

10. The semiconductor device of claim 6, wherein the second plurality of VTFET are in parallel.

11. The semiconductor device of claim 6, wherein the first plurality of VTFET and the second plurality of VTFET are in series.

12. The semiconductor device of claim 6, further comprising:
a backside power delivery network, wherein the backside power delivery network is on a backside of the wafer, and wherein the backside power delivery network is connected to a plurality of bottom source/drain region of the second plurality of VTFET, and wherein the backside power delivery network is selected from the group consisting of power or ground.

13. The semiconductor device of claim 6, wherein the contact is greater than the first width wide.

14. The semiconductor device of claim 6, wherein the contact from the frontside of the first plurality of VTFET connected to the bottom source/drain region is an output connection.

15. A semiconductor device comprising:
a first plurality of vertical-transport field-effect transistor (VTFET) on a wafer, wherein each VTFET of the first plurality of VTFET has a first width, and wherein the first width is a contacted poly pitch (CPP);
a second plurality of VTFET on the wafer, wherein the second plurality of VTFET are adjacent to the first plurality of VTFET;
a bottom source/drain region of the first plurality of VTFET extending at least the first width from a first VTFET of the first plurality of VTFET; and
a top contact connected to a top source/drain region of the second plurality of VTFET, wherein the top contact extending at least the first width from a second VTFET of the second plurality of VTFET.

16. The semiconductor device of claim 15, further comprising:
a bottom contact connected to the bottom source/drain region and a metal line in a first metal layer, wherein the first metal layer is above the first plurality of VTFET and second plurality of VTFET; and
wherein the top contact is connected to the metal line.

17. The semiconductor device of claim 15, further comprising:
an active region within the first width adjacent to the first plurality of VTFET and the second plurality of VTFET;
wherein the active region connects to a metal line in a first metal layer;
wherein the bottom source/drain region is connected to the active region; and
wherein the top contact is connected to the active region.

18. The semiconductor device of claim 15, wherein the first plurality of VTFET are in series.

19. The semiconductor device of claim 15, the top contact connected to the top source/drain region of the second plurality of VTFET is an output connection.

20. The semiconductor device of claim 15, further comprising:
a third plurality of VTFET adjacent to the first plurality of VTFET; and
an active region of the third plurality of VTFET, Wherein the active region extends inside the first width of the second plurality of VTFET.
